(19) United States
(12) Patent Application Publication
(10) Pub. No.: US 2016/0094033 A1
(43) Pub. Date: Mar. 31, 2016

(54) SVC COMPENSATION STRATEGY OPTIMIZATION METHOD

(71) Applicants: STATE GRID CORPORATION OF CHINA, Beijing (CN); STATE GRID GANSU ELETRIC POWER CORPORATION, Gansu (CN); STATE GRID GASU ELECTRIC POWER RESEARCH INSTITUTE, Gansu (CN); SICHUAN UNIVERSITY, Sichuan (CN)

(72) Inventors: WEI ZHENG, LANZHOU, GANSU PROVINCE (CN); CHEN LIANG, LANZHOU, GANSU PROVINCE (CN); WEIZHOU WANG, LANZHOU, GANSU PROVINCE (CN); YONG ZHI, LANZHOU, GANSU PROVINCE (CN); XIANYONG XIAO, CHENGDU, SICHUAN PROVINCE (CN); LIANGLIANG AN, LANZHOU, GANSU PROVINCE (CN); RUNQING BAI, LANZHOU, GANSU PROVINCE (CN); ZHENHUAN CHEN, LANZHOU, GANSU PROVINCE (CN); FUBO LIANG, LANZHOU, GANSU PROVINCE (CN); SAISAI NI, LANZHOU, GANSU PROVINCE (CN)

(21) Appl. No.: 14/894,291

(22) PCT Filed: May 27, 2014
(86) PCT No.: PCT/CN2014/000533

§ 371 Date: Nov. 25, 2015

(30) Foreign Application Priority Data
May 27, 2013 (CN) 201310201349.7

(51) Int. Cl. H02J 3/18; G01R 21/133; G05F 1/70

(52) U.S. Cl. CPC H02J 3/18; G05F 1/70; G01R 21/1331

(57) ABSTRACT

An SVC compensation strategy optimization method, comprising: calculating a weak voltage node in a fault state based on risk measure; calculating the weak voltage node in a normal state based on a static stability margin; and determining an optimal SVC distribution point and calculating the optimal configuration of SVC capacity. The SVC compensation strategy optimization method overcomes the defects in the prior art, such as low reliability, low optimization precision, poor applicability, etc., and has the advantages of high reliability, high optimization precision, and good applicability.

### TECHNICAL FIELD

The present invention relates to the Var compensation technical field, specifically to a Static Var Compensator (SVC) Compensation Strategy Optimization Method.

### BACKGROUND

With the rapid development of the power grid in China, said grid will become a super-large synchronous/asynchronous mixed interconnected power grid with the highest voltage grade, the maximum long distance power transmission capacity and the widest interconnected power grid coverage area in the near future. However, the power grid interconnection also inevitably brings some problems while bringing great benefit. The system structure and its running way are getting more and more complex and variable, easily leading to the chain reaction of accidents which will cause widespread blackout. This is proved by the successive major blackout accidents in several large power grids around the world in recent years.

With the increase of power use intensity in large cities and load centers and the application of super-high voltage long distance transmission lines, the stability problem of power system is getting more and more prominent. Besides, with the development of industrial technology, the impact loads of the industrial electric arc furnace, electric locomotive, steel rolling machine and large semiconductor AC equipment are increasing, the reactive power of these loads changes violently and may destabilize the system voltage. Therefore, improving the stability of interconnected power grid and inhibiting the voltage fluctuation have been becoming a hot spot of concern for people.

In order to improve the voltage stability of power grid, enhance the transmission capacity, reduce the grid loss, inhibit the low-frequency oscillation among areas, and meet the safe and reliable running requirements of electric system and the commercial running requirements of power market, it is urgently required to improve the controllability and adjustability of the system parameter. The researchers have been always searching more advanced and effective control measures. It has long been considered of changing the topology structure and parameter of network to adjust the line trend and of manufacturing some equipment such as fixed series or parallel compensation device to control the system trend. However, most of these devices are based on mechanical switches, the mechanical inertia limits the improvement of its running speed, its mechanical action has poor reliability and short service life, and cannot meet the demand of modern electric system trend adjustment and the demand for controlling in other aspects. Seeking new measure that can continuously, quickly and accurately control the system trend is always the objective.

With the development of high-power power electronic technology and the maturity of computer control technology, the Flexible AC Transmission System (FACTS) technology emerges as the times require. As one of the FACTS devices, the SVC is a static var compensator based on power electronic technology, and it can continuously and dynamically adjust the bus voltage of system, alleviate the impact of power system disturbance to bus voltage, and keep the bus voltage of power system within a normal scope. Different from traditional parallel capacitor and reactor, the SVC has the advantages of high response speed, smooth adjustment and dynamic tracking bus reactive power; and the SVC can be considered as the reactive power supply in the power system besides the generator and can also be considered as a pure reactive load. From the view of power grid structure, the SVC is a partial structure control device, which adjusts the dynamic structure of power grid at certain extent and guarantees the basic dynamic property of the power system. From the view of power system trend distribution, the SVC is a feedback compensation measure, the influence thereof on power system can be considered as the topology change to related parameter space to guarantee the partial topology equivalence of power system. In this sense, the selection of installation place and the optimization of installation capacity of the SVC are especially important.

The compensation strategy optimization technology of SVC reactive compensation device includes two sides: SVC optimized compensation spot and optimized capacity configuration.

As to the determination and selection of weak line and bus of power grid, i.e., reactive compensation device SVC compensation point, the prior art adopts the method of calculating the static load margin which represents the voltage stability of the system. The static load margin indicates the ratio of the difference between the total apparent power of load in critical running state and the total apparent power of load in normal state to the total apparent power in normal state, as shown in formula (1):

$$λ = \frac{{S}^{L} - {S}^{N}}{{S}^{N}} \qquad ( 1 )$$

In formula (1), λ indicates the static load margin; S^{L} indicates the total apparent power in critical running state; and S^{N} indicates the total apparent power in normal state.

The transition way of the power system from normal running state to critical state includes the ways of increasing the load at single-load node, increasing the load at multiple load nodes and increasing the load in the whole grid. Different load increasing way may obtain different static load margin. After determining the load increasing way, the critical point is uniquely determined. The prior art generally adopts the way of increasing load at single-load node to calculate the static load margin of each node, then rank the nodes, and determine the several nodes with minimal load margin as the voltage weak point, i.e., the most deserved compensable points of SVC compensation device.

When calculating the SVC optimized capacity configuration, the current method adopts multiple objective optimization algorithm, and the target function is shown as formula (2):

minf=I_{svc}+L_{grid} (2)

In formula (2), I_{svc} indicates the total invested maintenance cost of SVC; and L_{grid} indicates the grid loss of the system.

After adding the SVC at the compensation point, the corresponding invested maintenance cost will be caused according to the reactive capacity of SVC, and the system structure and trend will change so as to change the system grid loss. Therefore, it is desired to obtain the best capacity configuration of configuration point by the optimization calculation of the above formula.

The current SVC compensation strategy optimization method has following drawbacks:

(1) As to the determination of system weak line and bus, i.e., the selection and optimization technology of SVC compensation point, the current method only considers the stability in normal running state, but not technically analyzes the system stability and corresponding weak link in fault state. In the system chain fault state, the physical link and mathematic relation among all elements of the system are not clear, and this will prevent the original optimization technology from performing accurate and effective reactive compensation alleviation and voltage enhance function in the system chain fault state, even accelerate the system collapse.

(2) As to the capacity optimization configuration of SVC compensation device, in the multiple objective optimization target function used in prior art, two variables have different scales and quantities, therefore, in the multiple objective optimization process, shield phenomenon may occur, causing inaccurate optimization result and unavailable actual optimization strategy.

In view of the above, in the process of realizing the present invention, the inventor have found that the prior art at least has the disadvantages of low reliability, low optimization precision and poor applicability.

### SUMMARY OF THE INVENTION

The present invention aims to provide a SVC Compensation Strategy Optimization Method according to the above mentioned problems in order to realize the advantages of high reliability, high optimization precision and good applicability.

In order to realize the above mentioned objectives, the present invention adopts the following technical solution: a SVC Compensation Strategy Optimization Method mainly comprises:

a. Calculating a weak voltage node in a fault state based on risk measurement;

b. Calculating the weak voltage node in a normal state based on a static stability margin; and

c. Determining an optimal SVC distribution point and calculating the optimal configuration of SVC capacity.

Further, the step a specifically comprises:

a1. Credibility measurement: measuring the uncertainty of the power grid catastrophic accident by the credibility measurement and establishing the evaluation model of the catastrophic accident according to the reliability theory;

a2. Global fuzzy safety measurement: the ability of the element to bear the disturbance varies in certain region [D_{low}, Dᵤₚ]; when the disturbance is greater than Dᵤₚ, the element is unsafe; when the disturbance is less than D_{low}, the element is normal; when the disturbance occurs within said region, the element running state is uncertain and can be drawn by the region number; and the region number is a type of special fuzzy number, and the membership degree function can be used to draw the change trend;

a3. Risk measurement: the risk measurement Mᵣᵢₛₖ is i a comprehensive measurement to M_{cr} and M_{GFS} and is positively related to the M_{cr} M_{GFS}, it can be drawn by the Larsen operator, and the mathematical expression is:

Mᵣᵢₛₖ=M_{cr}M_{GFS} (14);

a4. SVC node distribution model algorithm based on risk measurement: on the basis of catastrophic accident risk evaluation method, analyzing the running risk of the power grid, forecasting the weak branch in accident process, obtaining the sequence of possible catastrophic accidents and the sequence of chain faults of the power grid, and providing basis for SVC compensation point.

Further, in the step a1, the credibility measurement M_{cr}(A) of occurrence of catastrophic accident A is:

$$\begin{matrix}{M}_{cr} ( A ) = \frac{1}{2} ( {M}_{pos} ( A ) + {M}_{nec} ( A ) ) ; \\ Wherein \text{:} & ( 3 ) \\ {M}_{nec} ( A ) = 1 - {M}_{pos} ( \overline{A} ) ; & ( 4 )\end{matrix}$$

In formula (3) and formula (4), Ā is the complementary set of A; and M_{nec}(A) indicates the impossibility degree of Ā;

According to formula (3) and formula (4), the value in the credibility measurement varies within [0,1]; when the value is 1, the accident A is inevitable; when the value is 0, the accident A is impossible; and when the value is between 0 and 1, the credibility of occurrence of the accident A increases with the increase of measurement.

Further, in the step a2, the over limit degree of the power system component is used to represent the chain fault severity, and 5 severity membership degrees δt(t=1, 2, . . . , 5) are used to respectively describe the severity of branch overload, load miss, bus voltage, active and reactive output of a generator.

Further, in the step a4, the N−1 accident is considered as the initial accident, ranking the risk measurements of all accident transmission stages, and the most dangerous accident in one stage is considered as the initial accident of the next stage; when the accident causes the non convergence of power grid trend or more than 20% of load loss, it is a catastrophic accident; and N is a natural number.

Further, the step b specifically comprises:

Obtaining the load margin of the system or node by the nonlinear planning method, and in the condition of meeting all limits of system, determining the maximum value of load increase in the power system, and the mathematical model thereof is:

min−λ (15);

The limiting condition (s.t.) of formula (15) is as follows:

$${P}_{gi} - {P}_{Li} - {V}_{i} {\sum }_{j ∈ i} {V}_{j} ( {G}_{ij} cos {θ}_{ij} + {B}_{ij} sin {θ}_{ij} ) - λ {b}_{p i} = 0$$

$${Q}_{gi} - {Q}_{Li} - {V}_{i} {\sum }_{j ∈ i} {V}_{j} ( {G}_{ij} sin {θ}_{ij} - {B}_{ij} cos {θ}_{ij} ) - λ {b}_{qi} = 0$$

$${Pg}_{i m i n} \leq {Pg}_{i} \leq {Pg}_{ima x} ( i = 1 , 2 , … , {n}_{G} )$$

$${Qg}_{im i n} \leq {Qg}_{i} \leq {Qg}_{i ma x}$$

$${V}_{i m i n} \leq {V}_{i} \leq {V}_{i ma x} ( i = 1 , 2 , … , n )$$

$${P}_{li m i n} \leq {P}_{li} \leq {P}_{lima x} ( i = 1 , 2 … , {n}_{l} )$$

In formula (15) and the limiting conditions thereof: n indicates the total number of nodes; P_{gi} and Q_{gi} respectively indicate the active and reactive power of the node i, P_{Li} and Q_{Li} respectively indicate the active and reactive load power of node i; Vᵢ and θᵢ respectively indicates the voltage amplitude and phase angle of the node i; the node admittance matrix element is Gᵢⱼ+Bᵢⱼ; bₚᵢ and b_{qi} respectively indicate the load increase directions.

In formula (15) and the limiting conditions thereof: nₗ indicates the amount of branches, Pgᵢₘᵢₙ and Pgᵢₘₐₓ respectively indicate the upper and lower limits of active treatment of the generator i; Qgᵢₘᵢₙ and Qgᵢₘₐₓ respectively indicates the upper and lower limits of reactive actions of the generator i; Vᵢₘᵢₙ and Vᵢₘₐₓ respectively indicates the upper and lower limits of voltage of the node i; Pₗᵢₘᵢₙ and Pₗᵢₘₐₓ indicate the upper and lower limits for the branch i to transmit the active power.

Further, the step c specifically includes:

c1. The multiple objective SVC capacity configuration optimization model;

c2. The fuzzy treatment of target function by using the fuzzy set theory method; and

c3. The fuzzy single objective optimization model.

Further, the step c1 specifically comprises:

In the process of configuring the SVC device to the power grid, it is required to consider both the increase of the system voltage stability and the cost of installing the SVC after installing the SVC. Therefore, when establishing the optimization model, the target function should include the change of voltage stability and the paid cost.

The target function:

Consider the target function of the static load margin:

F₁=maxλ (16);

Consider the target function of the investment fee:

$${F}_{2} = min {\sum }_{i ∈ Ω} {a}_{i} + {b}_{i} {y}_{i} ; \qquad ( 17 )$$

wherein: λ indicates the static load margin of the system; Ω indicates the selected reactive compensation node, yᵢ indicates the compensation reactive capacity of the compensation node i, and aᵢ and bᵢ respectively indicate the relationship parameters between the compensation price and the compensation capacity.

Limiting conditions:

$${P}_{gi} - {P}_{Li} - {V}_{i} {\sum }_{j ∈ i} {V}_{j} ( {G}_{ij} cos {θ}_{ij} + {B}_{ij} sin {θ}_{ij} ) - λ {b}_{pi } = 0$$

$${Q}_{gi} + {Q}_{ci} - {Q}_{Li} - {V}_{i} {\sum }_{j ∈ i} {V}_{j} ( {G}_{ij} sin {θ}_{ij} - {B}_{ij } cos {θ}_{ij} ) - λ {b}_{qi} = 0$$

$${Pg}_{im i n} \leq {Pg}_{i} \leq {Pg}_{ima x}$$

$${Qg}_{im i n} \leq {Qg}_{i} \leq {Qg}_{i ma x}$$

$${V}_{im i n} \leq {V}_{i} \leq {V}_{ima x}$$

$${P}_{li m i n} \leq {P}_{li} \leq {P}_{lima x}$$

$${Q}_{cim i n} \leq {Q}_{ci} \leq {Q}_{cima x}$$

wherein, P_{gi} and Q_{gi} respectively indicate the active and reactive power of the node i, P_{Li} and Q_{Li} respectively indicate the active and reactive load power of node i; Q_{ci} indicates the compensation capacity of the compensation node i; Vᵢ and θᵢ respectively indicates the voltage amplitude and phase angle of the node i I; the node admittance matrix element is Gᵢⱼ+Bᵢⱼ; bₚᵢ and b_{qi} respectively indicate the load increase directions.

Pgᵢₘᵢₙ and Pgᵢₘₐₓ respectively indicate the upper and lower limits of active treatment of the generator i; Qgᵢₘᵢₙ and Qgᵢₘₐₓ respectively indicates the upper and lower limits of reactive actions of the generator i; Vᵢₘᵢₙ and Vᵢₘₐₓ respectively indicates the upper and lower limits of voltage of the node i; Pₗᵢₘᵢₙ and P_{hd limax} indicate the upper and lower limits for the branch i to transmit the active power; and Q_{cimin} and Q_{cimax} respectively indicate the maximum value and minimal value of compensation capacity of the compensation node i.

Further, the step c2 specifically comprises:

1) The greater the static load margin, the better the voltage stability of system, so the target function F₁ belongs to the maximum target function, and the membership degree function μ(F₁) is selected as the linear monotonic increasing function:

$$μ ( {F}_{1} ) = \{ \begin{matrix}0 & if {F}_{1} \leq {F}_{1 m i n} \\ \frac{{F}_{1} - {F}_{1 m i n}}{{F}_{1 m ax} - {F}_{1 m i n}} & if {F}_{1 m i n} \leq {F}_{1} \leq {F}_{1 m a x} \\ 1 & if {F}_{1} \geq {F}_{1 ma x}\end{matrix} \qquad ( 18 )$$

wherein, F₁ₘᵢₙ indicates the unacceptable target value; F₁ₘₐₓ indicates the ideal target value.

2) The less the investment cost, the better the target function F₂, so the target function F₂ belongs to the minimal target function, and the membership degree function μ(F₂) is selected as the linear monotonic decreasing function:

$$μ ( {F}_{2} ) = \{ \begin{matrix}0 & if {F}_{2} \leq {F}_{2 m i n} \\ \frac{{F}_{2 m ax} - {F}_{2}}{{F}_{2 m ax} - {F}_{2 m i n}} & if {F}_{2 m i n} \leq {F}_{2} \leq {F}_{2 m a x} \\ 1 & if {F}_{2} \geq {F}_{2 m i n}\end{matrix} ; \qquad ( 19 )$$

wherein, F₂ₘₐₓ indicates the unacceptable target value; F₂ₘᵢₙ indicates the ideal target value. The diagram of linear monotonic increases or decreases membership function.

Further, the step c3 specifically comprises:

The decider applies different weights to all fuzzy target functions and converts the multiple objective functions into the fuzzy single objective function, and the optimization model of SVC capacity configuration can be expressed as:

$$F = max ( {\sum }_{i = 1}^{2} {ω}_{i} μ ( {F}_{i} ) ) ; \qquad ( 20 )$$

The limiting condition is the same as the limiting condition of the multiple objective optimization model established in formula (16) and formula (17).

The SVC Compensation Strategy Optimization Method in all embodiments of the present invention mainly comprises: calculating a weak voltage node in a fault state based on risk measurement; calculating the weak voltage node in a normal state based on a static stability margin; and determining an optimal SVC distribution point and calculating the optimal configuration of SVC capacity. Therefore, the risk measurement analysis technology can be combined with the original static load margin analysis method to analyze the reactive weak points of the whole system in the normal state and the fault state and provide the optimization solution of optimal SVC access point, thereby overcoming the disadvantages of the prior art of low reliability, low optimization precision and poor applicability and realizing the advantages of high reliability, high optimization precision and good applicability.

Other features and advantages of the present invention will be described in the following description, and partially be obvious in the description or known by implementing the present invention.

The technical solution of the present invention will be further described in detail below by way of drawings and embodiments.

### BRIEF DESCRIPTION OF THE DRAWINGS

The drawing is used to provide further understanding to the present invention, form one part of the description, and explain the invention together with the embodiments of the invention without limiting the present invention. In the drawings:

FIG. 1 is a schematic diagram of severity membership degree distribution rule;

FIG. 2 is a risk measurement evaluation flow chart of power grid chain accident;

FIG. 3 is a multiple objective conversion fuzzy membership function;

FIG. 4 is an implementation flow chart of SVC compensation strategy optimization method;

FIG. 5 is a simplified diagram of electric wiring of technical verification test system;

FIGS. 6(a)-(b) are the PV curve comparison of node 11 in Gansu Guazhou before and after the compensation; and

FIGS. 7(a)-(b) are the PV curve comparison of node 31 in Gansu Yumen before and after the compensation.

### DETAILED DESCRIPTION OF THE PREFERRED EMBODIMENTS

The preferred embodiment of the present invention will be described below in combination with the drawings, and it should be understood that the preferred embodiment described here is only used to describe and explain the present invention without limiting the present invention.

When solving the access point optimization problem of the SVC compensation, the prior art cannot accurately handle the weak links in system fault condition and therefore cannot accurately find the optimal access point. The present invention adopts the risk measurement analysis technology of using the risk measure of line chain accident in system to find the weak link in system fault state and combining the original optimization technology to find the optimal access point of SVC in normal and fault states of the system.

When optimizing the SVC capacity configuration in prior art, the variables in the multiple objective optimization target function have different dimensions, leading to the problem of inaccurate optimization result. The present invention adopts the fuzzy technology to fuzzify the target function by using the membership degree function, to convert the target function with dimension to the target function without dimension to provide it with comparability, and to provide each target function with different weights, thus converting multiple objective problems into single objective problem.

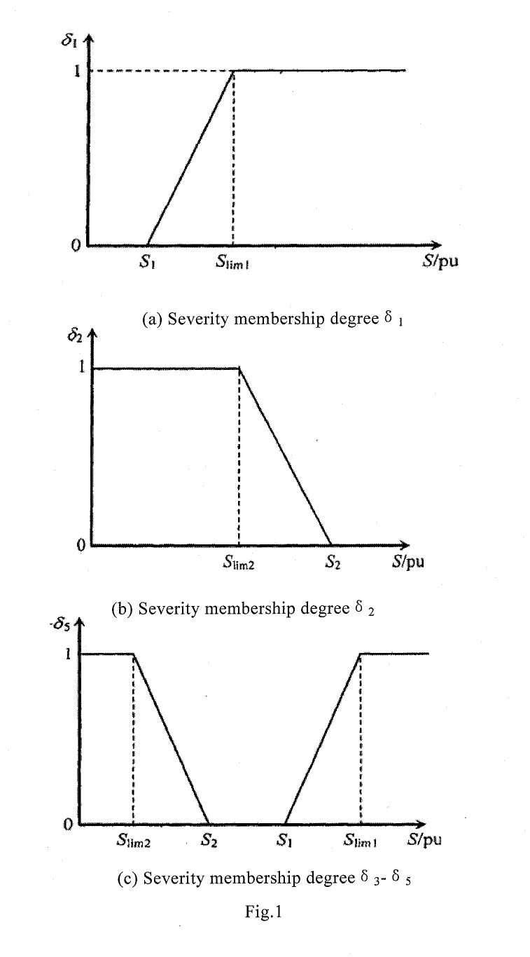

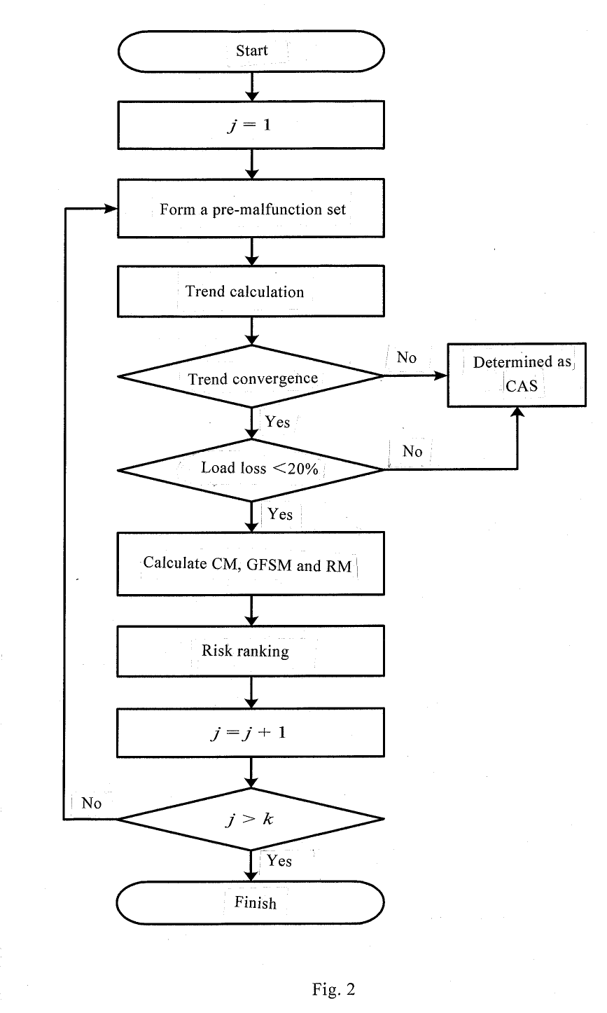

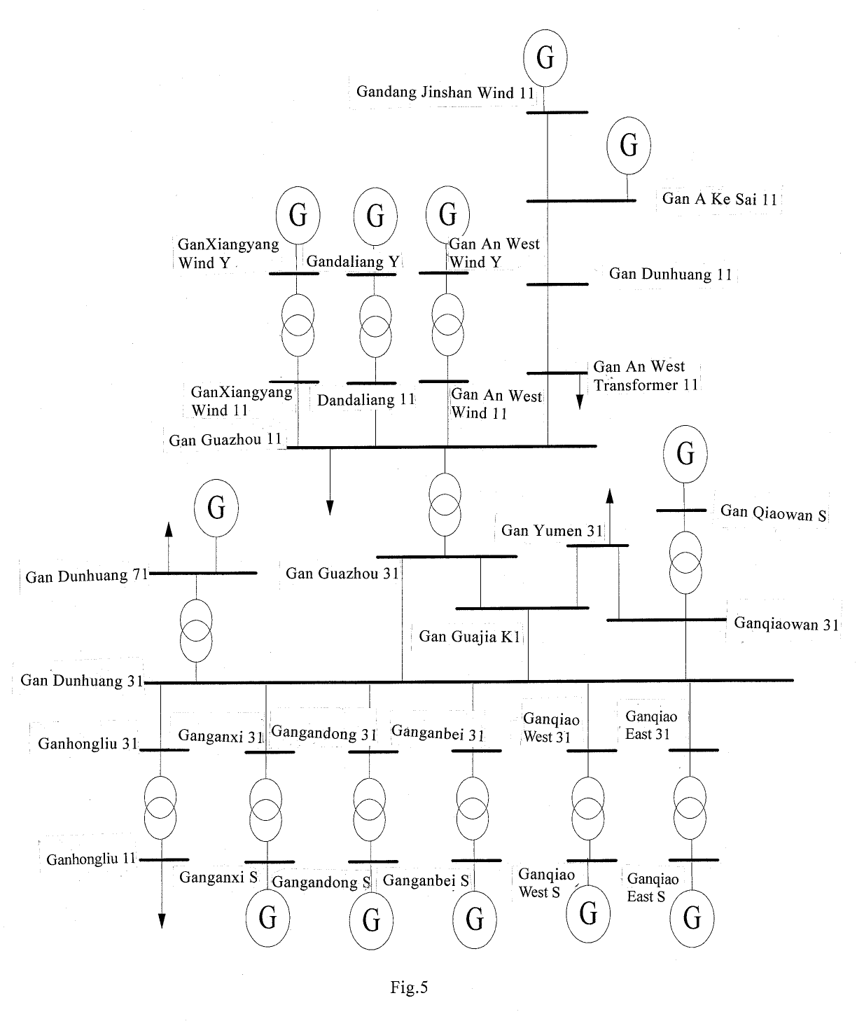

According to the embodiments of the present invention, as shown from FIG. 1 to FIG. 7, a SVC Compensation Strategy Optimization Method mainly comprises the following steps:

1. According to the reactive power in-situ balance principle, the optimal SVC access points should be located on two sides of the weakest branch. The power grid accident is combined with the safety, and the risk theory is used to identify the weak branch in power grid. The model adopts the N−1 accident as the initial accident, ranking the risk measurement of N−k accidents and identifying the sequence of possible accidents in power grid. According to the frequency of power grid branch in accident sequence and the influence degree thereof on the sequence, the weak branch of West Huanghe River power grid and the considered weak node are obtained.

2. The static load margin indicates the distance from the current running state to the system collapse, the less the static load margin, the worse the voltage stability, and the easier the voltage collapse after system disturbance. By calculating the static load margin of all nodes, the node with minimal static load margin is used as the SVC compensation node to effectively prevent the voltage collapse and guarantee safe and stable running of system.

3. Comprehensively considering the item 1 and the item 2 and determining the optimal distribution point of SVC compensation.

4. Meanwhile, simultaneously considering the system static load margin and the SVC device installation investment fees, establishing a multiple objective optimization model, and fuzzifying the target function to obtain the fuzzy single objective optimization model, and using the primal—dual interior point method to obtain the optimal compensation capacity of each compensation node.

5. Using the PSD-BPA power system analysis software to model the West Huanghe River power grid in Gansu, analyzing the safety and stability of the power grid before and after installing the SVC according to the technology in the present invention, and researching the risk of power grid before and after installing the SVC in system N−k accident in a computer of Intel(R) Core(TM) i3 CPU, 3.20 GHz, 2G and 32-bit operation system.

Specifically, referring to FIG. 1-FIG. 7, the complete technical solution of implementing the SVC Compensation Strategy Optimization Method in the above mentioned embodiment is as follows:

1. Fault Risk Evaluation Measurement System

(1) Credibility Measurement

In view of the above, the possibility measurement only subjectively describes the easiness of accident, actually, the accident with the possibility of 1 may not necessarily happen, i.e., the possibility measurement does not have the self-duality. In order to make up this defect, this embodiment adopts the credibility measurement to measure the uncertainty of catastrophic accident of the power grid, and establish the evaluation model of catastrophic accident according to the credibility theory.

The credibility measurement M_{cr}(A) of the catastrophic accident A is:

$$\begin{matrix}{M}_{c r} ( A ) = \frac{1}{2} ( {M}_{pos} ( A ) + {M}_{nec} ( A ) ) \\ wherein , & ( 3 ) \\ {M}_{nec} ( A ) = 1 - {M}_{pos} ( \overline{A} ) & ( 4 )\end{matrix}$$

In formula (3) and formula (4), Ā is the complementary set of A; and M_{nec}(A) indicates the impossibility degree of Ā;

According to formula (3) and formula (4), the value in the credibility measurement varies within [0,1]; when the value is 1, the accident A is inevitable; when the value is 0, the accident A is impossible; and when the value is between 0 and 1, the credibility of occurrence of the accident A is increased as the increase of measurement.

Taking Mₚₒₛ(Aⱼ) and Mₚₒₛ(Āⱼ) as examples, when the accident is transmitted to the j stage, if the current Iᵢⱼ of the branch Lᵢⱼ(i=1, 2, . . . , nⱼ) is a fuzzy variable, the corresponding membership function is μᵢⱼ(Iᵢⱼ). The possibility of multiple hidden failures is far less than the possibility of single hidden failure, so the influence of multiple hidden failure can be ignored, and it is considered that the set Bⱼ composed of the fault elements transmitted by the accident to all stages only has 1 branch Lₘⱼ that is cut off because of the hidden failure, and the current on the L_{if} before the cutting is Īᵢⱼ. According to the definition of joint reliability distribution function:

$$\begin{matrix}{M}_{pos} ( {A}_{j} ) = sup [ {⋀}_{{i = 1 \sim {n}_{j}}_{i \neq m}} {μ}_{ij} ( {I}_{ij} \geq {\overline{I}}_{ij} ) ⋀ {μ}_{mj} ( {I}_{mj} \leq {\overline{I}}_{mj} ) ] = 1 ⋀ 1 ⋀ … ⋀ 1 ⋀ {μ}_{mj} ( {\overline{I}}_{mj} ) = {μ}_{mj} ( {\overline{I}}_{mj} ) & ( 5 ) \\ {M}_{pos} ( {\overline{A}}_{j} ) = sup [ {⋀}_{{i = 1 \sim {n}_{j}}_{i \neq m}} {μ}_{ij} ( {I}_{ij} \leq {\overline{I}}_{ij} ) ⋀ {μ}_{mj} ( {I}_{mj} \geq {\overline{I}}_{mj} ) ] = {μ}_{1 j} ( {\overline{I}}_{1 j} ) ⋀ {μ}_{2 j} ( {\overline{I}}_{2 j} ) ⋀ … ⋀ {μ}_{{n}_{j} j} ( {\overline{I}}_{{n}_{j} j} ) ⋀ 1 = {⋀}_{{i = 1 \sim {n}_{j}}_{i \neq m}} {μ}_{ij} ( {\overline{I}}_{ij} ) & ( 6 )\end{matrix}$$

According to formula (5) and formula (6):

Mₚₒₛ(A)=Mₚₒₛ(A₁) [symbol] Mₚₒₛ(A₂) [symbol] Mₚₒₛ(Aₖ) (7)

M_{nec}(A)=1−Mₚₒₛ(Ā₁) [symbol] Mₚₒₛ(Ā₂) [symbol] . . . [symbol] Mₚₒₛ(Āₖ) (8)

(2) Global Fuzzy Safety Measurement

The severity of accident is drawn with the over-limit degree of elements such as branch, bus and generator. The traditional method obtains the global severity measurement M_{GS} of power grid by the weighted mean of element severity, this way ignoring the uncertainty of the element disturbance bearing capacity. In actual condition, the element disturbance bearing capacity always changes in a certain region [D_{low}, Dᵤₚ]. When the disturbance is greater than Dᵤₚ, the element is unsafe; when the disturbance is less than D_{low}, the element is normal; when the disturbance is within this region, the element running state is uncertain and can be drawn with the region number; and the region number is a type of special fuzzy number, and the membership degree function can be used to draw the change trend.

In the embodiment of the invention, 5 severity membership degrees δt(t=1, 2, . . . , 5) are used to describe the severity of branch overload, load miss, bus voltage, active and reactive output of a generator. δ1, δ2 and δ3-δ5 respectively represent the large, small and medium trapezoid distribution rule, referring to FIG. 1. Wherein, S indicates the current state parameter of the element, and the trapezoid distribution parameters S1 and S2 as well as Slim1 and Slim2 respectively indicate the thresholds for element safe running and for accident occurrence. All distribution parameters are standardized, and the set values are shown in Table 1.

TABLE 1
Parameter setting of trapezoid distribution

| Severity | | |
|---|---|---|
| membership | Distribution | |
| degree | rule | Parameter |
| δ1 | Large | S1 = 1.10 pu, Slim1 = 1.30 pu |
| δ2 | Small | Slim2 = 0.80 pu, S2 = 0.95 pu |
| δ3 | Medium | Slim2 = 0.90 pu, S2 = 0.95 pu, |
| | | S1 = 1.05 pu, Slim1 = 1.10 pu |
| δ4 | Medium | Slim2 = 0 pu, S2 = 0.90 pu, |
| | | S1 = 1.07 pu, Slim1 = 1.15 pu |
| δ5 | Medium | Slim2 = −0.02 pu, S2 = 0.90 pu, |
| | | S1 = 1.07 pu, Slim1 = 1.15 pu |

The severity of chain accidents is represented by the over-limit degree of power system components, and 5 severity membership degrees δt(t=1, 2, . . . , 5) are used to describe the severity of branch overload, load miss, bus voltage, active and reactive output of a generator. Specifically:

1) among the line overload severity, the line temperature over-limit expresses the line overload, and the expression is shown as formula (9):

$$Sev ( S ) = \{ \begin{matrix}0 & S < {S}_{1} \\ \frac{S - {S}_{1}}{{S}_{li m 1} - {S}_{1}} & {S}_{1} < S < {S}_{l im 1} \\ 1 & S > {S}_{li m 1}\end{matrix} \qquad ( 9 )$$

wherein, Sev(S) indicates the severity of line overload risk; S indicates the current trend of line, and S₁ [symbol] Sₗᵢₘ₁ respectively indicate the warning trend value and highest trend value of the line.

2) Load loss severity calculation formula, as shown in formula (10).

$$Sev ( L ) = \{ \begin{matrix}0 & Δ L < Δ {L}_{1} \\ \frac{Δ L - Δ {L}_{1}}{Δ {L}_{li m 1} - Δ {L}_{1}} & Δ {L}_{1} < Δ L < Δ {L}_{li m 1} \\ 1 & Δ L > Δ {L}_{l im 1}\end{matrix} \qquad ( 10 )$$

wherein, Sev(L) indicates the load loss severity; ΔL indicates the actual load loss; and ΔL₁ and ΔLₗᵢₘ₁ respectively indicate the load loss warning value and loss highest value.

3) Calculation formula of node state amount over-limit severity is shown in formula (11):

$$Sev ( X ) = \{ \begin{matrix}1 & X < {X}_{li m 2} , X > {X}_{li m 1} \\ \frac{X - {X}_{2}}{{X}_{li m 2} - {X}_{2}} & {X}_{li m 2} < X < {X}_{2} \\ 0 & {X}_{2} < X < {X}_{1} \\ \frac{X - {X}_{1}}{{X}_{li m 1} - {X}_{1}} & {X}_{1} < X < {X}_{li m 1}\end{matrix} \qquad ( 11 )$$

wherein, Sev(X) indicates the node state amount over-limit severity, X may be the voltage U, active P or reactive Q; and X₁, X₂, Xₗᵢₘ₁ and Xₗᵢₘ₂ indicate the state amount over-limit calculation threshold of all nodes.

The corresponding comprehensive severity membership degree δₜ^{s} can be obtained from the membership degree δₜ of the element fault severity:

$${δ}_{t}^{s} = {\sum }_{l = 1}^{r} {δ}_{t} ( l ) \qquad ( 12 )$$

In formula (12), l indicates the component l(l=1, 2, . . . , r) of δt corresponding element.

The global fuzzy safety measurement of power grid M_{GFS} is:

$${M}_{GFS} = {\prod }_{t = 1}^{5} {δ}_{t}^{s} \qquad ( 13 )$$

M_{GFS} comprehensively considers the influence of branch, bus and generator and reflects the influence degree of the disturbance on the power grid. The less the M_{GFS} value, the better the safety of power grid; and the greater the M_{GFS} value, the worse the safety of power grid.

In the coefficient selection process, the coefficient of voltage U in the node state amount to increase the influence of system voltage instability and evaluate the global voltage safety of system.

(3) Risk Measurement

The catastrophic accident of power grid has multiple uncertainties, so the risk measurement is generally used for evaluation.

The risk measurement Mᵣᵢₛₖ is a comprehensive measurement to M_{cr} and M_{GFS} and is positively related to the M_{cr} and M_{GFS}, it can be drawn by the Larsen operator, and the mathematical expression is:

Mᵣᵢₛₖ=M _{cr}M_{GFS} (14)

(4) SVC Node Distribution Model Algorithm Based on Risk Measurement

The research finds that most catastrophic accidents of power grid cause the large-scale spread for unstable voltage, and the SVC can quickly provide the system the reactive support in the accident process and improve the bus voltage. Therefore, the present application can, on the basis of catastrophic accident risk evaluation method, analyze the running risk of the power grid, forecast the weak branch in accident process, obtain the sequence of possible catastrophic accidents and the sequence of chain faults of the power grid, and provide basis for SVC compensation point.

The present invention can take the N−1 accident as the initial accident, ranking the risk measurements of all accident transmission stages, and the most dangerous accident in one stage is considered as the initial accident of the next stage; when the accident causes the non convergence of power grid trend or more than 20% of load loss, it is the catastrophic accident; and the uncertainty risk evaluation flow is shown in FIG. 2.

2. Static Load Margin

The load margin of a system or load can be obtained by the nonlinear planning method, and in the condition of meeting all limits of the system, the object is how to determine the maximum value of load increase in the power system, and the mathematical model is:

min−λ (15);

The limiting condition (s.t.) of formula (15) is as follows:

$${P}_{gi} - {P}_{Li} - {V}_{i} {\sum }_{j ∈ i} {V}_{j} ( {G}_{ij} cos {θ}_{ij} + {B}_{ij} sin {θ}_{ij} ) - λ {b}_{pi} = 0$$

$${Q}_{gi} - {Q}_{Li} - {V}_{i} {\sum }_{j ∈ i} {V}_{j} ( {G}_{ij} sin {θ}_{ij} - {B}_{ij} cos {θ}_{ij} ) - λ {b}_{qi} = 0$$

$${Pg}_{im i n} \leq {Pg}_{i} \leq {Pg}_{i ma x} ( i = 1 , 2 , … , {n}_{G} )$$

$${Qg}_{im i n} \leq {Qg}_{i} \leq {Qg}_{ima x}$$

$${V}_{imin} \leq {V}_{i} \leq {V}_{imax} ( i = 1 , 2 … , n )$$

$${P}_{limi n} \leq {P}_{li} \leq {P}_{lima x} ( i = 1 , 2 … , {n}_{l} )$$

In formula (15) and the limiting conditions thereof: n indicates the total number of nodes; P_{gi} and Q_{gi} respectively indicate the active and reactive power of the node i, P_{Li} and Q_{Li} respectively indicate the active and reactive load power of node i; Vᵢ and θᵢ respectively indicates the voltage amplitude and phase angle of the node i; the node admittance matrix element is Gᵢⱼ+Bᵢⱼ; bₚᵢ and b_{qi} respectively indicate the load increase directions.

In formula (15) and the limiting conditions thereof: nₗ indicates the amount of branches, Pgᵢₘᵢₙ and Pgᵢₘₐₓ respectively indicate the upper and lower limits of active treatment of the generator i; Qgᵢₘᵢₙ and Qgᵢₘₐₓ respectively indicates the upper and lower limits of reactive actions of the generator i; Vᵢₘᵢₙ and Vᵢₘₐₓ respectively indicates the upper and lower limits of voltage of the node i; Pₗᵢₘᵢₙ and Pₗᵢₘₐₓ indicate the upper and lower limits for the branch i to transmit the active power.

3. SVC Capacity Optimization Configuration Algorithm

(1) Optimization model of multiple objective SVC capacity configuration

In the process of configuring the SVC device to the power grid, it is required to consider both the increase of the system voltage stability and the cost of installing the SVC after installing the SVC, therefore, when establishing the optimization model, the target function should include the change of voltage stability and the fee paid;

The target function;

Considering the target function of the static load margin:

F₁=max λ, (16);

Considering the target function of the investment fee:

$${F}_{2} = min {\sum }_{i ∈ Ω} {a}_{i} + {b}_{i} {y}_{i} ; \qquad ( 17 )$$

wherein: λ indicates the static load margin of the system; Ω indicates the selected reactive compensation node, yᵢ indicates the compensation reactive capacity of the compensation node i, and aᵢ and bᵢ respectively indicate the relationship parameters between the compensation price and the compensation capacity.

Limiting Conditions:

$${P}_{gi} - {P}_{Li} - {V}_{i} {\sum }_{j ∈ i} {V}_{j} ( {G}_{ij} cos {θ}_{ij} + {B}_{ij} sin {θ}_{ij} ) - λ {b}_{pi} = 0$$

$${Q}_{gi} + {Q}_{ci} - {Q}_{Li} - {V}_{i} {\sum }_{j ∈ i} {V}_{j} ( {G}_{ij} sin {θ}_{ij} - {B}_{ij} cos {θ}_{ij} ) - λ {b}_{qi} = 0$$

$${Pg}_{imin} \leq {Pg}_{i} \leq {Pg}_{imax}$$

$${Qg}_{imin} \leq {Qg}_{i} \leq {Qg}_{imax}$$

$${V}_{imin} \leq {V}_{i} \leq {V}_{ima x}$$

$${P}_{limin} \leq {P}_{li} \leq {P}_{limax}$$

$${Q}_{cimin} \leq {Q}_{ci} \leq {Q}_{cimax}$$

wherein, P_{gi} and Q_{gi} respectively indicate the active and reactive power of the node i, P_{Li} and Q_{Li} respectively indicate the active and reactive load power of node i; Q_{ci} indicates the compensation capacity of the compensation node i; Vᵢ and θᵢ respectively indicates the voltage amplitude and phase angle of the node i; the node admittance matrix element is Gᵢⱼ+Bᵢⱼ; bₚᵢ and b_{qi} respectively indicate the load increase directions; Pgᵢₘᵢₙ and Pgᵢₘₐₓ respectively indicate the upper and lower limits of active treatment of the generator i; Qgᵢₘᵢₙ and Qgᵢₘₐₓ respectively indicates the upper and lower limits of reactive actions of the generator i; Vᵢₘᵢₙ and Vᵢₘₐₓ respectively indicates the upper and lower limits of voltage of the node i; Pₗᵢₘᵢₙand Pₗᵢₘₐₓ indicate the upper and lower limits for the branch i to transmit the active power; and Q_{cimin} and Q_{cimax} respectively indicate the maximum value and minimal value of compensation capacity of the compensation node i.

(2) Fuzzification Treatment of the Target Function

In the multiple objective optimization model established above, the static load margin and the investment cost of installing the SVC device of the system are contradictory and limit each other. In general significance, the multiple objective function does not have the best result, that is, it is impossible to optimize all target functions, instead, and the function has a group of effective results having mutual advantages and disadvantages according to different objectives and meeting the limiting conditions.

Each target function has different dimensions, so the target functions are not comparable with each other, and the method of fuzzification set theory can solve this problem by firstly fuzzifying the target function by using the membership degree function, converting the target function with dimension into the target function without dimension to provide comparability, and providing each target function with different weights, thus converting the multiple objective problem into the single objective problem.

1) The greater the static load margin, the better the voltage stability of system, so the target function F₁ belongs to the maximum target function, and the membership degree function μ(F₁) is selected as the linear monotonic increasing function:

$$μ ( {F}_{1} ) = \{ \begin{matrix}0 & if {F}_{1} \leq {F}_{1 m i n} \\ \frac{{F}_{1} - {F}_{1 m i n}}{{F}_{1 ma x} - {F}_{1 m i n}} & if {F}_{1 m i n} \leq {F}_{1} \leq {F}_{1 m ax} \\ 1 & if {F}_{1} \geq {F}_{1 m ax}\end{matrix} \qquad ( 18 )$$

wherein, F₁ₘᵢₙ indicates the unacceptable target value; F₁ₘₐₓ indicates the ideal target value.

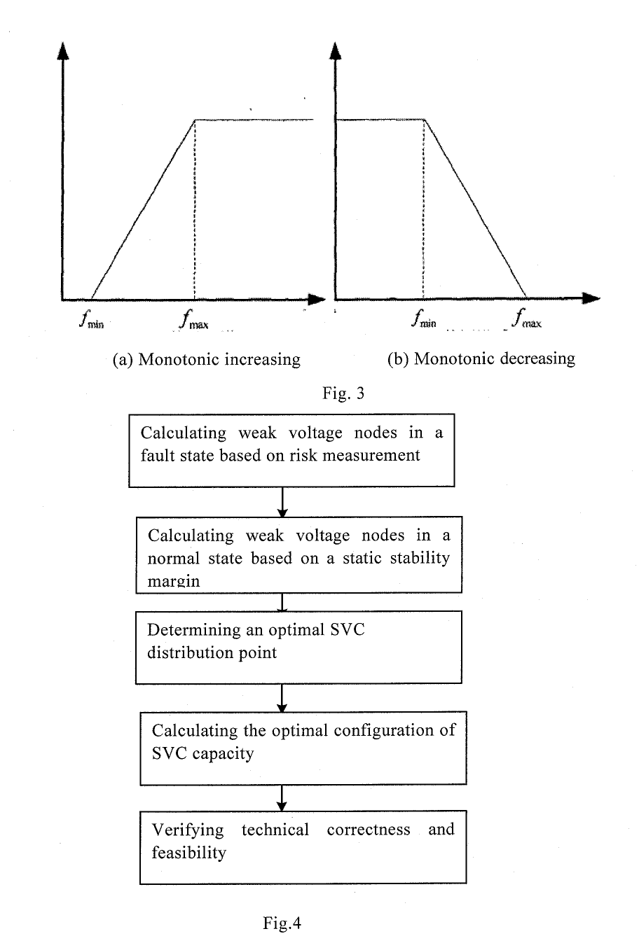

2) The less the investment cost, the better the target function F₂, so the target function F2 belongs to the minimal target function, and the membership degree function μ(F₂) is selected as the linear monotonic decreasing function:

$$μ ( {F}_{2} ) = \{ \begin{matrix}0 & if {F}_{2} \leq {F}_{2 m ax} \\ \frac{{F}_{2 ma x} - {F}_{2}}{{F}_{2 ma x} - {F}_{2 m i n}} & if {F}_{2 m i n} \leq {F}_{2} \leq {F}_{2 m ax} \\ 1 & if {F}_{2} \geq {F}_{1 m i n}\end{matrix} \qquad ( 19 )$$

wherein, F₂ₘₐₓ indicates the unacceptable target value; F₂ₘᵢₙ indicates the ideal target value, and the diagram of linear monotonic increasing or decreasing membership function is shown in FIG. 3.

(3) Fuzzy Single Objective Optimization Model

The decider provides different weights to all fuzzy target functions and converts the multiple objective functions into the fuzzy single objective function, and the optimization model of SVC capacity configuration can be expressed as:

$$F = max ( {\sum }_{i = 1}^{2} {ω}_{i} μ ( {F}_{i} ) ) ; \qquad ( 20 )$$

The limiting condition is the same as the limiting condition of the multiple objective optimization model established in formula (16) and formula (17).

4. Below will exemplify the specific application and verification of all above mentioned embodiments to verify the technical correctness and feasibility of the above mentioned SVC Compensation Strategy Optimization Method;

(1) The Test Network of Technical Verification Implementation

The test network of technical verification is the West Huanghe River power grid in Gansu, and the simplified diagram of system electric wiring is shown in FIG. 5 in section 5. The required information includes the network parameter of the whole power grid, the element parameter and the price of SVC device.

(2) Final compensation strategy is shown in Table 2.

TABLE 2
SVC compensation location and compensation capacity

| | SVC compensation |
|---|---|
| Compensation node | capacity/Mvar |
| Gansu Hongliu 31 | 143 |
| Gansu Dunhuang 31 | 458 |
| Gansu Guazhou 31 | 138 |
| Gansu Guazhou 11 | 95 |
| Gansu Dangjinshan wind | 69.2 |
| field 11 | |

(3) Comparison of Risk Measurement

Table 3 lists the change of risk measurement before and after the compensation. The calculation layer amount is 3, and the top 10 highest risk values are listed in the comparison.

TABLE 3
Comparison of calculation results of risk measurement

| Calculation result | | Calculation result | | Calculation result | |
|---|---|---|---|---|---|
| on the first layer | | on the second layer | | on the third layer | |
| the top 10 | the last 10 | the top 10 | the last 10 | the top 10 | the last 10 |
| highest | highest | highest | highest | highest | highest |
| sequence risk | sequence risk | sequence risk | sequence risk | sequence risk | sequence risk |
| values before | values after | values before | values after | values before | values after |
| compensation | compensation | compensation | compensation | compensation | compensation |
| 0.660711 | 0.539422 | 5.245392 | 3.268788 | 6.685667 | 4.137418 |
| 0.514425 | 0.379479 | 4.348637 | 3.251822 | 6.660483 | 4.135580 |
| 0.485469 | 0.379257 | 4.331710 | 3.233984 | 6.638323 | 4.124500 |
| 0.484794 | 0.378288 | 4.309629 | 3.225816 | 6.405220 | 4.122435 |
| 0.484763 | 0.311640 | 4.300160 | 3.225142 | 6.374375 | 4.121326 |
| 0.484478 | 0.295320 | 4.294920 | 3.214415 | 6.313687 | 4.120538 |
| 0.472842 | 0.288144 | 4.285009 | 2.597864 | 6.301657 | 4.098649 |
| 0.442821 | 0.287920 | 4.260807 | 2.447739 | 6.286619 | 4.090470 |
| 0.441937 | 0.287785 | 4.249552 | 2.423476 | 6.286023 | 4.084272 |
| 0.423108 | 0.286950 | 3.722775 | 2.422895 | 6.277229 | 4.076745 |

(4) Comparison of static load margin is shown in Table 4.

TABLE 4
comparison of static load margin
before and after SVC compensation

| | Before the | After the |
|---|---|---|
| | compensation | compensation |
| Static load margin | 0.2027 | 0.4187 |
| SVC investment | 0 | 2242.66 |
| cost/ten-thousand Yuan | | |

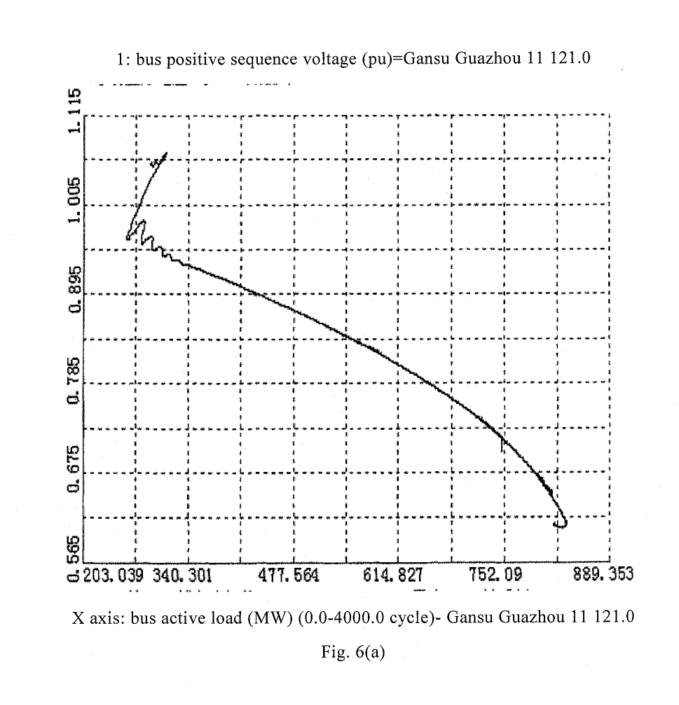

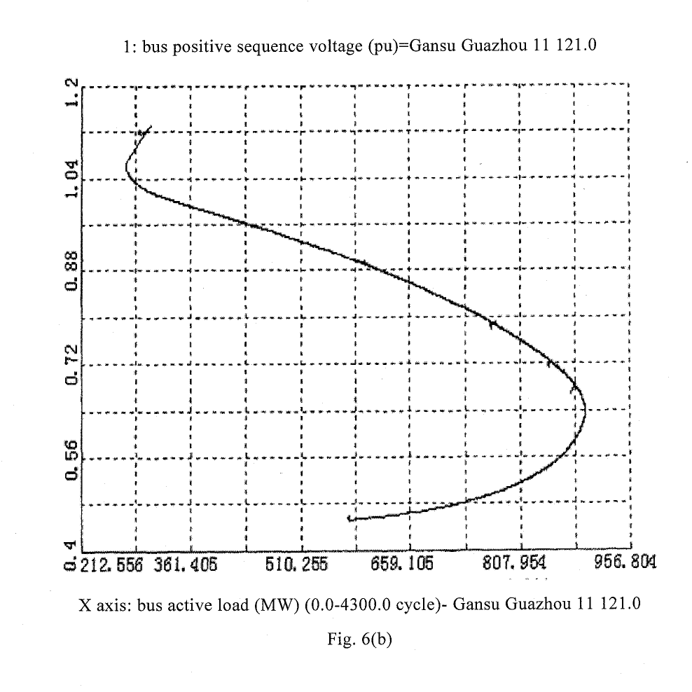

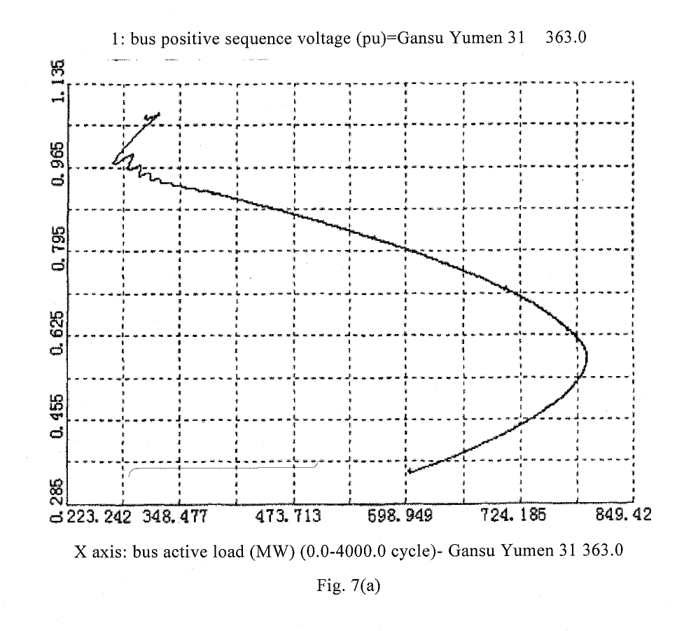

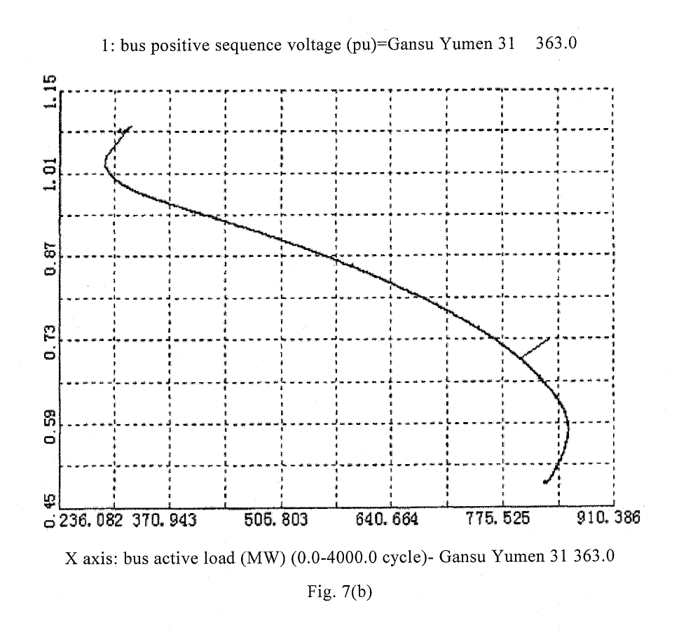

(5) The comparison diagram of load node PV curves is shown in FIG. 6 and FIG. 7 in section 5.

In view of the above, all embodiments in the present invention combine the risk measurement analysis technology with original static load margin analysis method to perform the optimization plan of analyzing the reactive weak point of the whole system in normal state and fault state, thus providing the optimal SVC access point. Therefore, according to the risk measurement analysis technology, the system weak point of the system in chain accident state can be obtained, the corresponding weak point is accessed with the SVC device to compensate the reactive power for the system, enhance the system voltage, and prevent the large-scale blackout accident of power system and the great economic loss and social influence.

At last, it should be noted that: the foregoing description is only made to the preferred embodiment of the present invention and does not intend to limit the invention. Although the present invention is described in detail referring to the above mentioned embodiments, those skilled in the art can also modify the technical solution described in the above embodiments, or equivalently replace some technical features. Any modification, equivalent replacement and improvement within the spirit and principle of the invention should all be included in the scope of protection of the invention.

1. A static var compensator (SVC) compensation strategy optimization method comprising:
a. calculating weak voltage nodes in a fault state based on risk measurement;
b. calculating weak voltage nodes in a normal state based on a static stability margin; and
c. determining optimal SVC distribution point and calculating optimal configuration of SVC capacity.

2. The SVC compensation strategy optimization method according to claim 1, wherein the step a specifically comprises:
a1. credibility measurement: measuring the uncertainty of the power grid catastrophic accident by the credibility measurement and establishing the evaluation model of the catastrophic accident according to the reliability theory;
a2. global fuzzy safety measurement: the ability of the element to bear the disturbance varies in certain region [D_{1ow}, Dₚ]; when the disturbance is greater than Dᵤₚ, the element is unsafe; when the disturbance is less than D_{low}, the element is normal; when the disturbance occurs within this region, the element running state is uncertain and can be drawn with the region number; and the region number is a type of special fuzzy number, and the membership degree function can be used to draw the change trend;
a3. risk measurement: the risk measurement Mᵣᵢₛₖ is a comprehensive measurement to M_{cr} and M_{GFS} and is positively related to the M_{cr} and M_{GFS}, it can be drawn by the Larsen operator, and the mathematical expression is:
Mᵣᵢₛₖ=M_{cr}M_{GFS} (14)
a4. SVC node distribution model algorithm based on risk measurement: on the basis of catastrophic accident risk evaluation method, analyzing the running risk of the power grid, forecasting the weak branch in accident process, obtaining the sequence of possible catastrophic accidents and the sequence of chain faults of the power grid, and providing basis for SVC compensation point.

3. The SVC compensation strategy optimization method according to claim 2, wherein in the step a1, the credibility measurement AKA) of occurrence of the catastrophic accident A is:
$$\begin{matrix}{M}_{cr} ( A ) = \frac{1}{2} ( {M}_{pos} ( A ) + {M}_{nec } ( A ) ) ; \\ wherein \text{:} & ( 3 ) \\ {M}_{nec} ( A ) = 1 - {M}_{pos} ( \overline{A} ) ; & ( 4 )\end{matrix}$$
in formula (3) and formula (4), A is the complementary set of A; and M_{nec}(A) indicates the impossibility degree of Ā;
according to formula (3) and formula (4), the value in the credibility measurement varies within [0,1]; when the value is 1, the accident A is evitable; when the value is 0, the accident A is impossible; and when the value is between 0 and 1, the credibility of occurrence of the accident A increases with the increase of measurement.

4. The SVC compensation strategy optimization method according to claim 2, wherein in the step a2, the over limit degree of the power system component is used to represent the chain fault severity, and 5 severity membership degrees δt(t=1, 2, . . . , 5) are used to describe the severity of branch overload, load miss, bus voltage, generator active and reactive output.

5. The SVC compensation strategy optimization method according to claim 2, wherein in the step a4, the N−1 accident is considered as the initial accident, then rank the risk measurements of all accident transmission stages, and the most dangerous accident in one stage is considered as the initial accident of the next stage; when the accident causes the non convergence of power grid trend or more than 20% of load loss, it is a catastrophic accident; and N is a natural number.

6. The SVC compensation strategy optimization method according to claim 1, the step b specifically comprises:
obtaining the load margin of the system or node by the nonlinear planning method, and in the condition of meeting all limits of system, determining the maximum value of load increase in the power system, and the mathematical model thereof is:
min−λ (15);
the limiting condition (s.t.) of formula (15) is as follows:
$${P}_{gi} - {P}_{Li} - {V}_{i} {\sum }_{j ∈ i} {V}_{j} ( {G}_{ij} cos {θ}_{ij} + {B}_{ij} sin {θ}_{ij} ) - λ {b}_{pi} = 0$$
$${Q}_{gi} + {Q}_{ci} - {Q}_{Li} - {V}_{i} {\sum }_{j ∈ i} {V}_{j} ( {G}_{ij} sin {θ}_{ij} - {B}_{ij} cos {θ}_{ij} ) - λ {b}_{qi} = 0$$
$${Pg}_{imin} \leq {Pg}_{i} \leq {Pg}_{imax} ( i = 1 , 2 , … , {n}_{G} )$$
$${Qg}_{imin} \leq {Qg}_{i} \leq {Qg}_{imax} \\ {V}_{imin} \leq {V}_{i} \leq {V}_{ima x} ( i = 1 , 2 … , n )$$
$${P}_{limin} \leq {P}_{li} \leq {P}_{limax} ( i = 1 , 2 … , {n}_{l} )$$
in formula (15) and the limiting conditions thereof: n indicates the total number of nodes; P_{gi} and Q_{gi} respectively indicate the active and reactive power of the node i, P_{Li} and Q_{Li} respectively indicate the active and reactive load power of node i; V, and θᵢ respectively indicates the voltage amplitude and phase angle of the node i; the node admittance matrix element is Gᵢⱼ+Bᵢⱼ; bₚᵢ and b_{qi} respectively indicate the load increase directions;
in formula (15) and the limiting conditions thereof: nₗ indicates the amount of branches, Pgᵢₘᵢₙ and Pgᵢₘₐₓ respectively indicate the upper and lower limits of active treatment of the generator i; Qgᵢₘᵢₙ Vᵢₘₐₓ respectively indicates the upper and lower limits of reactive actions of the generator i; Vᵢₘᵢₙ and Vᵢₘₐₓ respectively indicates the upper and lower limits of voltage of the node i; Pₗᵢₘᵢₙ and Pₗᵢₘₐₓ indicate the upper and lower limits for the branch i to transmit the active power.

7. The SVC compensation strategy optimization method according to claim 1, the step c specifically comprises:
c1. the multiple objective SVC capacity configuration optimization model;
c2. the fuzzification treatment of target function by using the method of fuzzy set theory; and
c3. the fuzzy single objective optimization model.

8. The SVC compensation strategy optimization method according to claim 7, the step c1 specifically comprises:
in the process of configuring the SVC device to the power grid, it is required to consider both the increase of the system voltage stability and the cost of installing the SVC after installing the SVC , therefore, when establishing the optimization model, the target function should include the change of voltage stability and the fee paid;
the target function:
considering the target function of the static load margin:
F₁=max λ (16);
considering the target function of the investment fee:
$${F}_{2} = min {\sum }_{i ∈ Ω} {a}_{i} + {b}_{i} {y}_{i} ; \qquad ( 17 )$$
wherein: λ indicates the static load margin of the system; Ω indicates the selected reactive compensation node, yᵢ indicates the compensation reactive capacity of the compensation node i, and aᵢ and bᵢ respectively indicate the relationship parameters between the compensation price and the compensation capacity;
limiting condition:
$${P}_{gi} - {P}_{Li} - {V}_{i} {\sum }_{j ∈ i} {V}_{j} ( {G}_{ij} cos {θ}_{ij} + {B}_{ij} sin {θ}_{ij} ) - λ {b}_{pi} = 0$$
$${Q}_{gi} + {Q}_{ci} - {Q}_{Li} - {V}_{i} {\sum }_{j ∈ i} {V}_{j} ( {G}_{ij} sin {θ}_{ij} - {B}_{ij} cos {θ}_{ij} ) - λ {b}_{qi} = 0$$
$${Pg}_{imin} \leq {Pg}_{i} \leq {Pg}_{imax}$$
$${Qg}_{imin} \leq {Qg}_{i} \leq {Qg}_{imax}$$
$${V}_{imin} \leq {V}_{i} \leq {V}_{ima x}$$
$${P}_{limin} \leq {P}_{li} \leq {P}_{limax}$$
$${Q}_{cimin} \leq {Q}_{ci} \leq {Q}_{cimax}$$
wherein, P_{gi} and Q_{gi} respectively indicate the active and reactive power of the node i, P_{Li} and Q_{Li} respectively indicate the active and reactive load power of node i; Q_{ci} indicates the compensation capacity of the compensation node i; Vᵢ and θᵢ respectively indicates the voltage amplitude and phase angle of the node i; the node admittance matrix element is Gᵢⱼ+Bᵢⱼ; bₚᵢ and b_{qi} respectively indicate the load increase directions;
Pgᵢₘᵢₙ and Pgᵢₘₐₓ respectively indicate the upper and lower limits of active treatment of the generator i; Qgᵢₘᵢₙ and Qgᵢₘₐₓ respectively indicates the upper and lower limits of reactive actions of the generator ; Vᵢₘᵢₙ and Vᵢₘₐₓ respectively indicates the upper and lower limits of voltage of the node i; Pₗᵢₘᵢₙ and Pₗᵢₘₐₓ indicate the upper and lower limits for the branch i to transmit the active power; and Q_{cimin} and Q_{cimax} respectively indicate the maximum value and minimal value of compensation capacity of the compensation node i.

9. The SVC compensation strategy optimization method according to claim 7, the step c2 specifically comprises:
1) the greater the static load margin, the better the voltage stability of system, so the target function F₁ belongs to the maximum target function, and the membership degree function μ(F₁) is selected as the linear monotonic increasing function:
$$μ ( {F}_{1} ) = \{ \begin{matrix}0 & if {F}_{1} \leq {F}_{1 m i n} \\ \frac{{F}_{1} - {F}_{1 m i n}}{{F}_{1 ma x} - {F}_{1 m i n}} & if {F}_{1 m i n} \leq {F}_{1} \leq {F}_{1 m ax} \\ 1 & if {F}_{1} \geq {F}_{1 m ax}\end{matrix} \qquad ( 18 )$$
wherein, F₁ₘᵢₙ indicates the unacceptable target value; F₁ₘₐₓ indicates the ideal target value;
2) the less the investment cost, the better the target function F₂, so the target function F₂ belongs to the minimal target function, and the membership degree function μ(F₂) is selected as the linear monotonic decreasing function:
$$μ ( {F}_{2} ) = \{ \begin{matrix}0 & if {F}_{2} \leq {F}_{2 m ax} \\ \frac{{F}_{2 ma x} - {F}_{2}}{{F}_{2 ma x} - {F}_{2 m i n}} & if {F}_{2 m i n} \leq {F}_{2} \leq {F}_{2 m ax} \\ 1 & if {F}_{2} \geq {F}_{2 m i n}\end{matrix} ; \qquad ( 19 )$$
wherein, F₂ₘₐₓ indicates the unacceptable target value; F₂ₘᵢₙ indicates the ideal target value, and the diagram of linear monotonic increasing or decreasing membership function.

10. The SVC compensation strategy optimization method according to claim 7, the step c3 specifically comprises:
the decider applies different weights to all fuzzy target functions and converts the multiple objective functions into the fuzzy single objective function, and the optimization model of SVC capacity configuration can be expressed as:
$$F = max ( {\sum }_{i = 1}^{2} {ω}_{i} μ ( {F}_{i} ) ) ; \qquad ( 20 )$$
the limiting condition is the same as the limiting condition of the multiple objective optimization model established in formula (16) and formula (17).
